(19) United States
(12) Patent Application Publication
(10) Pub. No.: US 2008/0297048 A1
(43) Pub. Date: Dec. 4, 2008

(54) Light Emitting Diode Construction

(75) Inventor: Markus Cornelius Vermeulen, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 12/094,625

(22) PCT Filed: Nov. 20, 2006
(86) PCT No.: PCT/IB2006/054337

§ 371 Date: May 22, 2008

(30) Foreign Application Priority Data
Nov. 24, 2005 (EP) 05111230.8

(51) Int. Cl. H01L 33/00

(52) U.S. Cl. 313/512

(57) ABSTRACT

A light emitting diode (LED) construction is disclosed, which comprises at least one LED unit (1); at least a first kind of LED die (3) of a first material; at least a second kind of LED die (4) of a second material; and a sealing member (5), comprising a wavelength converting material (6), wherein said at least first kind of LED die (3) is electrically addressable separately from said at least second kind of LED die (4), said at least one LED unit (1) comprises LED dies (3, 4) of both kinds, and at least one continuous portion of said sealing member (5), comprising wavelength converting material (6), is positioned to receive light emitted from both kinds of LED dies (3, 4). The LED construction further comprises means (7) for adjustment of a colour temperature resulting from said LED construction.

The present invention relates to a light emitting diode (LED) construction in which the colour temperature output value can be adjusted. It also relates to a method for adjusting the colour temperature output value of such a LED construction, and to means for adjusting the colour temperature output value.

Most white-light LEDs (light emitting diodes) employ a LED die emitting a short wavelength (blue, violet or ultraviolet) and a wavelength converter, which absorbs light from the die and undergoes secondary emission at a longer wavelength. Such diodes, therefore, emit light of two or more wavelengths, that when they combine, appear as white. The most common wavelength converter materials are termed phosphors, which exhibit luminescence when they absorb energy from another radiation source.

White light is commonly described by its colour temperature, which is the temperature (in Kelvins) at which a perfect black body would emit the same spectrum.

White LEDs currently on the market are available in two main colour temperature variations: cool white (5000-6500 K) and warm white (3200-4000 K). All of these LEDs are based on phosphor converted blue LEDs.

Currently LED based solutions for changing colour temperature are based on either:
Using two separate LEDs (one warm white, one cold white) which are both driven at a different intensity and where an optical integration needs to take place to mix both colour temperatures together, thus resulting in a colour temperature somewhere between the two extremes of both LEDs.
Using two separate LEDs (one cool white, one amber) where the cool white LED is driven at its highest intensity and where amber is gradually added to move the colour temperature impression to white.

US 2002/0048177 discloses a LED arrangement producing a colour temperature adjustable white light. The LED arrangement includes one or more white LEDs and one or more coloured LEDs. The light output from the coloured LEDs combines with the white light to produce a resultant light having a desired colour temperature. The intensity of the coloured light output is adjustable by a user so as to vary the colour temperature of the resultant light.

One drawback of the prior art solutions is that they always need a separate integration chamber to mix the colours properly since the light does not come out of a single source. A separate integration chamber leads to a larger device, which is more difficult to construct to optimally mix the colours. When a smaller or less optimally designed integration chamber is used, the individual colours will not be fully mixed and can hence be distinguished.

Therefore, there remains a need for improved white light LEDs which are simple and can be easily adjusted to produce white light of a desired colour temperature.

An object of the present invention is to create an improved white light emitting LED. This object is achieved by a light emitting diode (LED) construction comprising

at least one LED unit;

at least a first kind of LED die of a first material;

at least a second kind of LED die of a second material; and

a sealing member, comprising a wavelength converting material,

wherein said at least first kind of LED die is electrically addressable separately from said at least second kind of LED die, said at least one LED unit comprises LED dies of both kinds, and at least one continuous portion of said sealing member, comprising wavelength converting material, is positioned to receive light emitted from both kinds of LED dies. The LED construction is characterised by further comprising means for adjustment of a colour temperature resulting from said LED construction.

Thereby, movement from cool white to warm white without the need for an integration chamber is enabled. Further, the colour temperature can be easily changed by the end-user.

Said first kind of LED die is preferably a blue LED die, and said first material may be selected from InGaN (Indium Gallium Nitride) and GaN (Gallium Nitride).

Said second kind of LED die is preferably an amber LED die, and said second material may be selected from AlInGaP (Indium Gallium Aluminum Phosphide), GaAsP (Gallium Arsenide Phosphide) and GaP (Gallium Phosphide).

The wavelength converting material may e.g. be yttrium-aluminum-garnet doped with cerium, praseodymium, europium or combinations thereof, for example (YAG:Ce), (YAG:Ce,Pr), and (YAG:Ce,Eu).

The means for adjustment of a colour temperature resulting from said LED construction may for example use Pulse Width Modulation, wherein the LED dies are together switched on for 100% of the time, said first kind of LED die being switched on for n % of the time, and said second kind of LED die being switched on for (100−n) % of the time.

The invention also relates to a method for adjustment of the colour temperature output value of a LED construction as defined above.

In addition, the present invention relates to means for adjustment of a colour temperature resulting from a LED construction, said LED construction comprising at least one LED unit; at least a first kind of LED die of a first material; at least a second kind of LED die of a second material; and a sealing member, comprising a wavelength converting material, wherein said at least first kind of LED die is electrically addressable separately from said at least second kind of LED die, said at least one LED unit comprises LED dies of both kinds, and at least one continuous portion of said sealing member, comprising wavelength converting material, is positioned to receive light emitted from both kinds of LED dies.

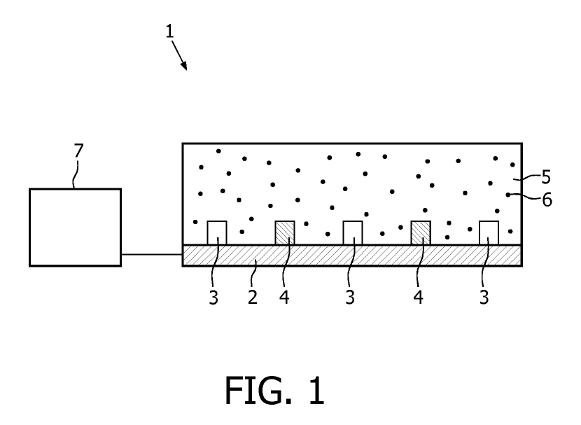

FIG. 1 shows a cross-sectional view of a LED unit according to the invention.

The present invention makes it possible to, within one LED package, make a phosphor converted white LED which can change from cool white to warm white.

It is commonly known to put multiple dies, rather than a single die, in white LEDs. Over the dies, a layer of phosphor is put which converts the blue light into (cool) white.

A LED construction according to the preamble of claim 1 is known from US 2005/0082974, which describes a way of adding red LED dies to a standard white LED to improve the colour rendering properties.

The present inventors have now, unexpectedly, found a way to be able to adjust the colour temperature values based on a LED construction according to the preamble of claim 1. Previously, it has not been possible to move from cold white to warm white, or vice versa, within ONE LED construction.

The adjustment of the colour temperature value emitted by the LED construction is achieved by including means having the ability to adjust the emitted colour temperature to a pre-selected value.

With reference to FIG. 1, a LED construction according to the invention comprises at least one LED unit (1) comprising a substrate (2) on which a first kind of LED dies (3) and a second kind of LED dies (4) are arranged. The first kind of LED dies (3) can be electrically addressed separately from the second kind of LED dies (4) (not shown). A sealing member (5) comprising wavelength converting material (6) is arranged over the dies (3), (4). The LED construction further comprises means (7) for adjustment of a colour temperature resulting from said LED construction.

The means (7) for adjustment of the colour temperature is constructed to allow an end-user to set a desired output colour temperature. Based on the desired output value set, the means (7) for adjustment of the colour temperature has the ability to vary the intensities of the first kind of LED die and the second kind of LED die until the desired output value is reached.

Suitable means (7) for adjustment of the colour temperature use Pulse Width Modulation, where the blue LED and the amber LED are together switched on for 100% of the time. The blue LED is switched on for a certain duration where the amber LED is switched on for the remainder of the time. I.e., if the blue LED is switched on for n % of the time, the amber LED is switched on for (100−n) % of the time. In this way, any mix between the colours can be realized. However, alternative methods may also be used according to the present invention.

In a preferred embodiment of the present invention, amber LED dies replace a few of the current blue LED dies of a conventional white LED unit. Both kinds of dies, i.e. the blue LED dies and the amber LED dies, are covered by a sealing member comprising wavelength converting material, i.e. phosphors. Since both kinds of dies are covered by the same sealing member, the phosphors comprised in the sealing member get two functions:

1) as a converter to convert the blue light into white light;
2) as a diffusor to mix the amber light and the white light.

Thus, switching on dies of both kinds will not result in a white light, since the phosphors will mix amber light with the white light generated by the phosphors via the blue LED dies.

For example, as a starting point a very cool white light, around 6000 K, could be used, and switching on the amber LED dies will make the LED colour warmer. Hence, the cooler the colour of the LED without driving the amber dies, the wider the color temperature variation. Any means to vary the intensity of the LED can be used to create the desired LED colour temperature.

LED dies of other colours than amber, e.g. red, could also be used in combination with the blue LED dies in order to achieve the desired effect. However, amber LED dies are preferred to use in the present invention as amber LEDs, without any other additions, closest resemble the colour temperature of an extremely warm while LED. Further to that, using amber has the least detriminal effect on the colour rendition of the LED.

By “electrically addressable separately” is meant that each kind of LED die can be controlled separately, i.e. each kind of LED die can be accessed electronically without affecting the other kind(s).

The blue LED dies according to the invention may for example be made of InGaN (Indium Gallium Nitride) or GaN (Gallium Nitride). InGaN is the most commonly used BLUE high output LED. In addition to blue LED dies, violet or ultraviolet LED dies may be used according to the invention.

The amber LED dies according to the invention may for example be made of AlInGaP (Indium Gallium Aluminum Phosphide), GaAsP (Gallium Arsenide Phosphide) or GaP (Gallium Phosphide), preferably AlInGaP.

As used herein, “a LED unit” relates to a subassembly comprising one or more LED dies, a mounting frame, electrical interconnect and optical provisions to extract the light.

As used herein, “a LED die” relates to a semiconductor material which has the ability to generate visible or invisible light.

It is to be understood that two or more different kinds of LED dies can be used according to the present invention, although the described embodiment discloses two kinds of LED dies only.

As used herein, “a sealing member” relates to a material or composition of materials which protects the LED die against external influences. It should also function as a buffer between the LED die and the ambient and match the thermal properties of all materials thus reducing mechanical stress. The sealing member may e.g. be made of polycarbonate, optionally used with a silicone GEL to match the thermal behaviour. One continuous portion of said sealing member, comprising wavelength converting material, shall be positioned to receive light emitted from both kinds of LED dies.

As used herein, “a wavelength converting material” relates to a material which ahs the ability to convert one (monochromatic) wavelength into another wavelength thus changing the colour of the light emitted. A wavelength converting material is commonly referred to as a phosphor. Typically used phosphors are composed of an inorganic host substance containing an optically active dopant. Yttrium aluminum garnet (YAG) is a common host material, and for diode applications, it is usually doped with one of the rare-earth elements or a rare-earth compound. Cerium is a common dopant element in YAG phosphors designed for white light emitting diodes. Examples of phosphors for use in the present invention are yttrium-aluminum-garnet doped with cerium, praseodymium, europium or combinations thereof, for example (YAG:Ce), (YAG:Ce,Pr), and (YAG:Ce,Eu). Also non-YAG based phosphors can be applied.

The wavelength converting material is generally uniformly dispersed in the sealing member. To avoid colour differences across the wavelength converting material, the material should be dispersed as evenly as possible.

A LED construction according to the present invention normally comprises an array of LED units according to the invention.

The LED construction according to the invention is easy to manufacture as both the blue as well as the amber LED dies are covered by the same phosphor. Therefore, basically any conventional LED construction which can handle multiple dies in one package and phosphor to create cool white can be used.

As the LED construction is not changed compared to using only blue dies, the cost of the LED can be the same as a LED which cannot handle colour temperature variation. As blue dies are more expensive than red/amber dies, the LED could even become cheaper.

The invention may be used for any lighting application, such as (high-end) office lighting, halogen replacement, desk illumination and other general lighting applications.

1. A light emitting diode (LED) construction comprising
at least one LED unit (1);
at least a first kind of LED die (3) of a first material;
at least a second kind of LED die (4) of a second material; and
a sealing member (5), comprising a wavelength converting material (6),
wherein said at least first kind of LED die (3) is electrically addressable separately from said at least second kind of LED die (4), said at least one LED unit (1) comprises LED dies (3, 4) of both kinds, and at least one continuous portion of said sealing member (5), comprising wavelength converting material (6), is positioned to receive light emitted from both kinds of LED dies (3, 4),
characterized in that said LED construction further comprises means (7) for adjustment of a colour temperature resulting from said LED construction.

2. A LED construction according to claim 1, wherein said first kind of LED die (3) is a blue LED die.

3. A LED construction according to claim 1, wherein said first material is selected from InGaN (Indium Gallium Nitride) and GaN (Gallium Nitride).

4. A LED construction according to claim 1, wherein said second kind of LED die (4) is an amber LED die.

5. A LED construction according to claim 1, wherein said second material is selected from AlInGaP (Indium Gallium Aluminum Phosphide), GaAsP (Gallium Arsenide Phosphide) and GaP (Gallium Phosphide).

6. A LED construction according to claim 1, wherein said wavelength converting material (6) is yttrium-aluminum-garnet doped with cerium, praseodymium, europium or combinations thereof, for example (YAG:Ce), (YAG:Ce,Pr), and (YAG:Ce,Eu).

7. A LED construction according to claim 1, wherein said means for adjustment of a colour temperature resulting from said LED construction uses Pulse Width Modulation.

8. A LED construction according to claim 7, wherein in said Pulse Width Modulation said first kind of LED die and said second kind of LED die are together switched on for 100% of the time, said first kind of LED die being switched on for n % of the time, and said second kind of LED die being switched on for (100−n) % of the time.

9. A method for adjustment of the colour temperature output value of a LED construction according to claim 1, comprising
setting a desired output value;
varying the intensities of said first kind of LED die (3) and said second kind of LED die (4) until said desired output value is reached.

10. Means for adjustment of a colour temperature resulting from a LED construction, said LED construction comprising
at least one LED unit (1);
at least a first kind of LED die (3) of a first material;
at least a second kind of LED die (4) of a second material; and
a sealing member (5), comprising a wavelength converting material (6),
wherein said at least first kind of LED die (3) is electrically addressable separately from said at least second kind of LED die (4), said at least one LED unit (1) comprises LED dies (3, 4) of both kinds, and at least one continuous portion of said sealing member (5), comprising wavelength converting material (6), is positioned to receive light emitted from both kinds of LED dies (3, 4).
